(19) United States
(12) Patent Application Publication
(10) Pub. No.: US 2006/0138492 A1
(43) Pub. Date: Jun. 29, 2006

(54) CMOS image sensor and method for fabricating the same

(76) Inventors: Hee Sung Shim, Seoul (KR); Tae Woo Kim, Icheon city (KR)

Correspondence Address: Song K. Jung;MCKENNA LONG & ALDRIDGE LLP, 1900 K Street, N.W., Washington, DC, 20006, US

(21) Appl. No.: 11/318,575

(22) Filed: Dec. 28, 2005

(30) Foreign Application Priority Data
Dec. 29, 2004 (KR) 10-2004-0114781

(51) Int. Cl. H01L 31/113

(52) U.S. Cl. 257/292

(57) ABSTRACT

A CMOS image sensor and a method for fabricating the same are disclosed, in which an impurity ion area is formed in a semiconductor substrate to form a transfer path for optical charges. Dead zone and dark current characteristics are thereby simultaneously improved. The CMOS image sensor includes a first conductive type semiconductor substrate, a device isolation film, a gate electrode, a second conductive type first impurity ion area and a first conductive type first impurity ion area formed with a deposition structure in the semiconductor substrate below the gate electrode, a second conductive type second impurity ion area, and a first conductive type second impurity ion area formed on a surface of the second conductive type second impurity ion area.

This application claims the benefit of Korean Patent Application No. 10-2004-0114781, filed on Dec. 29, 2004, which is hereby incorporated by reference for all purposes as if fully set forth herein.

### BACKGROUND OF THE INVENTION

1. Field of the Invention

The present invention relates to a complementary metal-oxide semiconductor (CMOS) image sensor and a method for fabricating the same. More particularly, the present invention relates to a CMOS image sensor and a method for fabricating the same in which dead zone characteristics, having a trade-off with dark current characteristics, are improved along with the dark current characteristics.

2. Discussion of the Related Art

Generally, an image sensor is a semiconductor device that converts optical images to electrical signals. The image sensor is classified into a charge coupled device (CCD) and a CMOS image sensor.

The CCD has drawbacks in its fabricating process because of a complicated driving mode, high power consumption, and multistage photolithographic processes. Also, it is difficult for a control circuit, a signal processing circuit, and an analog-to-digital converter to be integrated in a CCD chip. Thus, the CCD is not suitable for use in slim sized products. However, CMOS image sensors have received attention as the next generation technology for overcoming the drawbacks of CCDs.

The CMOS image sensor employs a switching mode that sequentially detects outputs of unit pixels using MOS transistors by forming the MOS transistors to correspond to the number of the unit pixels on a semiconductor substrate. CMOS technology that uses a control circuit and a signal processing circuit as peripheral circuits is employed.

The CMOS image sensor has advantages in that power consumption is low because of the CMOS technology. Also, a fabricating process is simple because of a relatively small number of photolithographic processing steps. Further, since the CMOS image sensor allows a control circuit, a signal processing circuit and an analog-to-digital converter to be integrated in its chip, it has an advantage in that a slim sized product can be obtained. Therefore, the CMOS image sensor is widely used for various application fields such as digital still cameras and digital video cameras.

A related art CMOS image sensor will be described with reference to FIGS. 1 and 2. FIG. 1 is a layout illustrating a unit pixel of a 4T type CMOS image sensor including four transistors, and FIG. 2 is an equivalent circuit 100 diagram illustrating the unit pixel of the CMOS image sensor shown in FIG. 1.

In the unit pixel of the 4T type CMOS image sensor, as shown in FIGS. 1 and 2, a photodiode (PD) 20 is formed in a wide portion of an active area 10, and gate electrodes 110, 120, 130, and 140 of four transistors, are formed to respectively overlap the other portions of the active area 10. A transfer transistor Tx, a reset transistor Rx, a drive transistor Dx, and a selection transistor Sx are respectively formed by the gate electrodes 110, 120, 130 and 140.

Impurity ions are implanted into the active area 10 of each transistor except portions below the gate electrodes 110, 120, 130 and 140, so that source and drain areas of each transistor are formed. Thus, a power voltage Vdd is applied to the source and drain areas between the reset transistor Rx and the drive transistor Dx, and a power voltage Vss is applied to the source and drain areas at one side of the selection transistor Sx.

The transfer transistor Tx transfers optical charges generated by the photodiode to a floating diffusion (FD) layer. The reset transistor Rx controls and resets the potential of the floating diffusion layer. The drive transistor Dx serves as a source follower. The selection transistor Sx serves as a switching transistor to read a signal of the unit pixel.

A method for fabricating the aforementioned related art CMOS image sensor will be described with reference to FIG. 3A to FIG. 3G. FIG. 3A to FIG. 3G are sectional views taken along line I-I′ of the unit pixel of the CMOS image sensor shown in FIG. 1.

First, as shown in FIG. 3A, a lightly doped P type (P—) epitaxial layer 2 is formed on a P type semiconductor substrate 1 defined by an active area and a device isolation area using a mask. Then, the lightly doped P type epitaxial layer 2 is etched at a predetermined depth by exposing and developing processes using the mask to form a trench. An oxide film is formed on the epitaxial layer 2. The trench is filled with the oxide film by a chemical mechanical polishing (CMP) process so as to form a device isolation film 3 in the device isolation area.

Impurity ions are implanted into the surface of the epitaxial layer 2 to correspond to the active area to form a P type impurity ion area 4. The P type impurity ion area 4 is used to control a threshold voltage in a channel area of the transfer transistor and to pin a surface voltage in the photodiode so as to reduce a dark current.

As shown in FIG. 3B, a gate insulating film and a conductive layer are sequentially formed on the entire surface of the substrate and then selectively dry-etched to form a gate insulating film 5 and a gate electrode 6 of each transistor including the transfer transistor.

As shown in FIG. 3C, a photoresist film is coated on the entire surface of the substrate and then removed by exposing and developing processes to form a photoresist pattern 7 that exposes the photodiode. The photoresist pattern 7 is formed to partially cover the active area adjacent the device isolation film 3 and partially exposes the gate electrode 6. N type impurity ions are implanted into the epitaxial layer 2 of the exposed photodiode by high energy ion implantation to form an N type impurity ion area 8 of the photodiode. The photoresist pattern 7 is then removed.

As shown in FIG. 3D, after the N type impurity ion area 8 is formed, a photoresist pattern 9 is formed to expose the photodiode. Then, P type impurity ions are implanted into the surface of the N type impurity ion area 8 to form a second P type impurity ion area 10 of the photodiode. The second P type impurity ion area 10 may alternatively be formed as follows.

Instead of the process shown in FIG. 3D, where the N type impurity ion area 8 is formed, FIG. 3E shows an alternative step. As shown in FIG. 3E. an insulating film is deposited on the entire surface of the device and then is dry-etched back to form spacers 11 at sides of the gate electrode 6 and the photoresist pattern 9 that exposes the photodiode. Then, P type impurity ions are implanted into the surface of the N type impurity ion area 8 to form the second P type impurity ion area 10.

As shown in FIG. 3F, after the photoresist pattern 9 is removed, a source and drain area, or a floating diffusion layer 12, of each transistor is formed by heavily implanting N type impurity ions into a drain area at one side of the gate electrode 6 using a mask.

Then, color filter layers and microlenses may be formed. Thus, the CMOS image sensor of the related art is completely fabricated.

In the related art CMOS image sensor, the photodiode converts signals of light into electrical signals to generate optical charges. The generated optical charges move to the floating diffusion layer so as to gate the drive transistor Dx if the transfer transistor Tx is turned on. However, as shown in FIG. 3D, if the P type impurity ions are implanted before the spacers are formed, the epitaxial layer below the spacers is pinned. Characteristics of a dark current may be improved but the P type impurity ion doping level increases. As the P type impurity ion doping level increases, a potential barrier of the source area of the transfer transistor increases to reduce transfer efficiency of the optical charges. A problem then occurs in that a dead zone is formed. In the dead zone no signal is generated for a certain time period after light enters the sensor.

Furthermore, as shown in FIG. 3F, if the P type impurity ions are implanted after the spacers are formed at the sidewalls of the gate electrode, transfer efficiency of the optical charges may be improved. However, the surface of the photodiode is damaged during the dry-etching process that forms the spacers. Dark current is thereby increased.

### SUMMARY OF THE INVENTION

Accordingly, the present invention is directed to a CMOS image sensor and a method for fabricating the same that substantially obviates one or more problems due to limitations and disadvantages of the related art.

An advantage of the present invention is to provide a CMOS image sensor and a method for fabricating the same in which an impurity ion area is formed in a semiconductor substrate to form a transfer path for optical charges, thereby simultaneously improving a dead zone characteristic and a dark current characteristic.

Another advantage of the present invention is to provide a CMOS image sensor and a method for fabricating the same, in which leakage current of the transfer transistor can be reduced.

Additional features and advantages of the invention will be set forth in the description which follows, and will be apparent from the description, or may be learned by practice of the invention. The objectives and other advantages of the invention may be realized and attained by the structure and method particularly pointed out in the written description and claims hereof as well as the appended drawings.

To achieve these and other advantages and in accordance with the purpose of the invention, as embodied and broadly described, a CMOS image sensor includes a first conductive type semiconductor substrate defined by an active area and a device isolation area, a device isolation film formed in the first conductive type semiconductor substrate corresponding to the device isolation area, a gate electrode formed on the first conductive type semiconductor substrate corresponding to a transistor area of the active area, a second conductive type first impurity ion area and a first conductive type first impurity ion area formed with a deposition structure in the semiconductor substrate below the gate electrode, a second conductive type second impurity ion area formed in the semiconductor substrate of a photodiode area, and a first conductive type second impurity ion area formed on a surface of the second conductive type second impurity ion area.

In another aspect of the present invention, a method for fabricating a CMOS image sensor includes forming a first conductive type first impurity ion area on a surface of an active area of a first conductive type semiconductor substrate defined by the active area and a device isolation area, forming a second conductive type first impurity ion area below the first conductive type first impurity ion area corresponding to a transistor area of the active area, forming a gate electrode on the semiconductor substrate corresponding to the transistor area, forming a second conductive type second impurity ion area in the semiconductor substrate corresponding to a photodiode area of the active area, and forming a first conductive type second impurity ion area on a surface of the second conductive type second impurity ion area.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention. In the drawings:

FIG. 1 is a layout illustrating a unit pixel of a 4T type CMOS image sensor including four transistors according to the related art;

FIG. 2 is an equivalent circuit diagram illustrating the unit pixel of the CMOS image sensor shown in FIG. 1;

FIG. 3A to FIG. 3F are sectional views of a CMOS image sensor fabricated by a method according to related art methods; and

FIG. 4A to FIG. 4F are sectional views of a CMOS image sensor fabricated by a method according to an exemplary embodiment of the present invention.

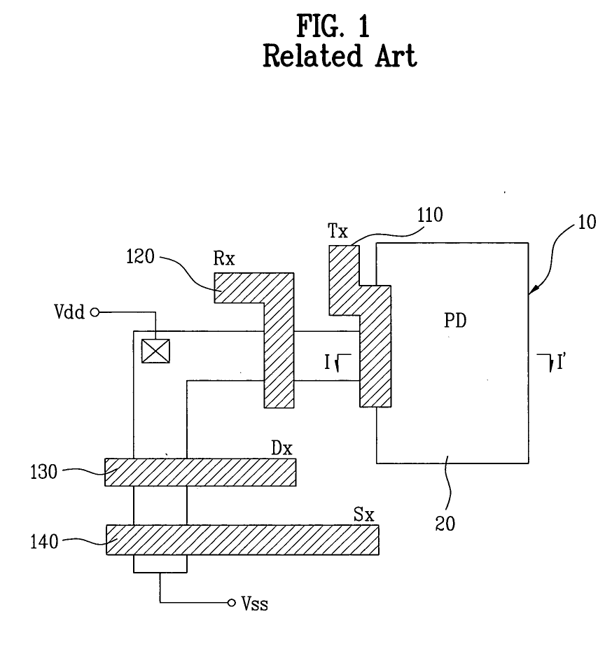

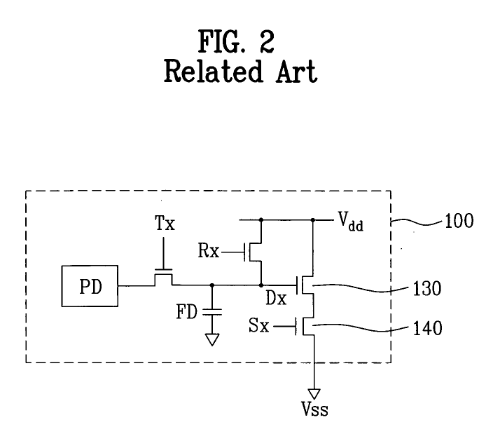

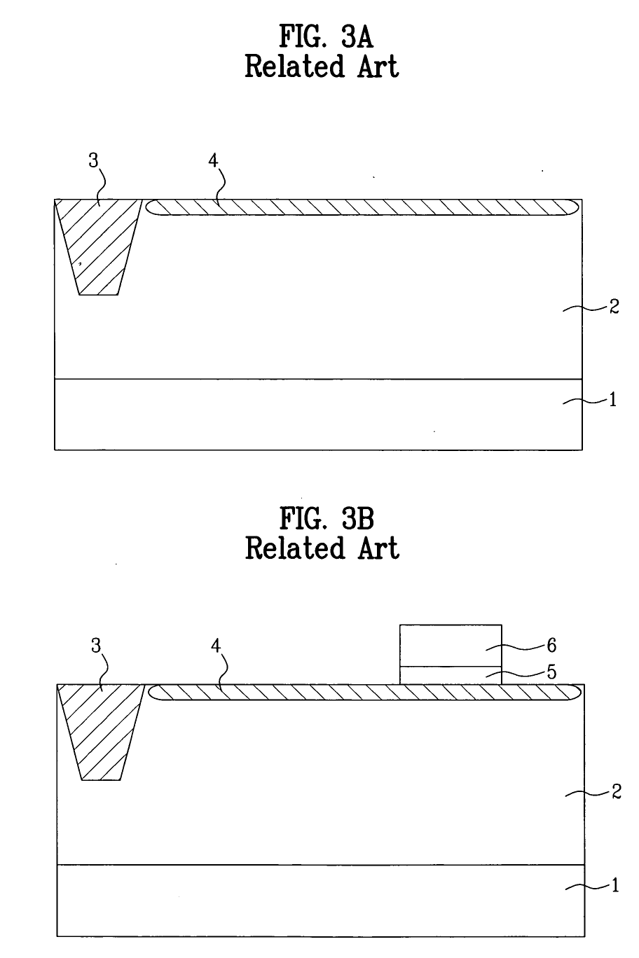

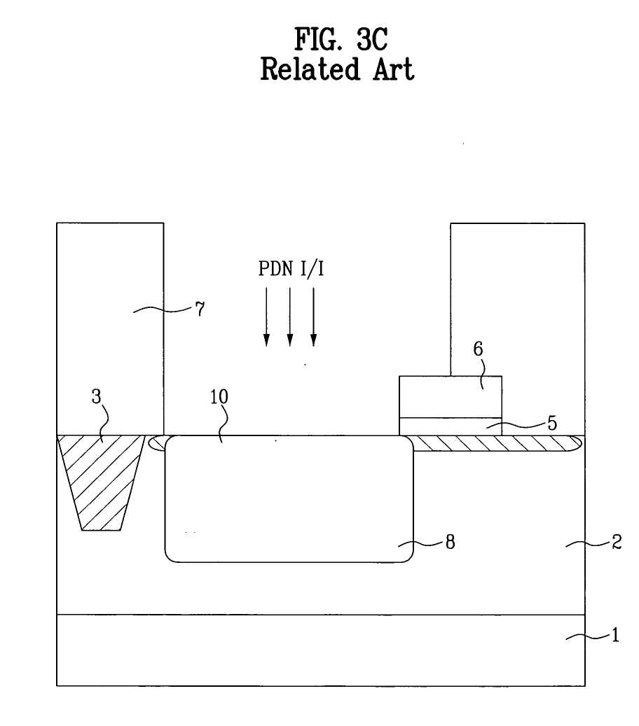

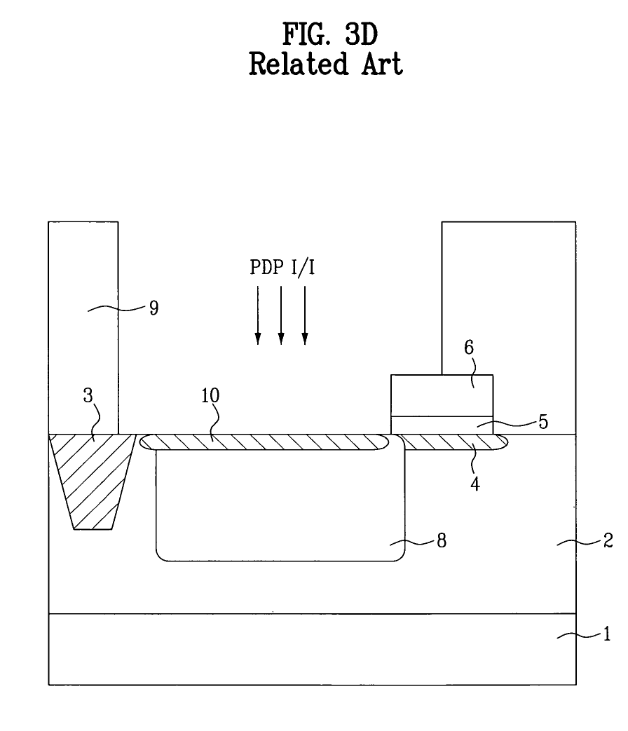

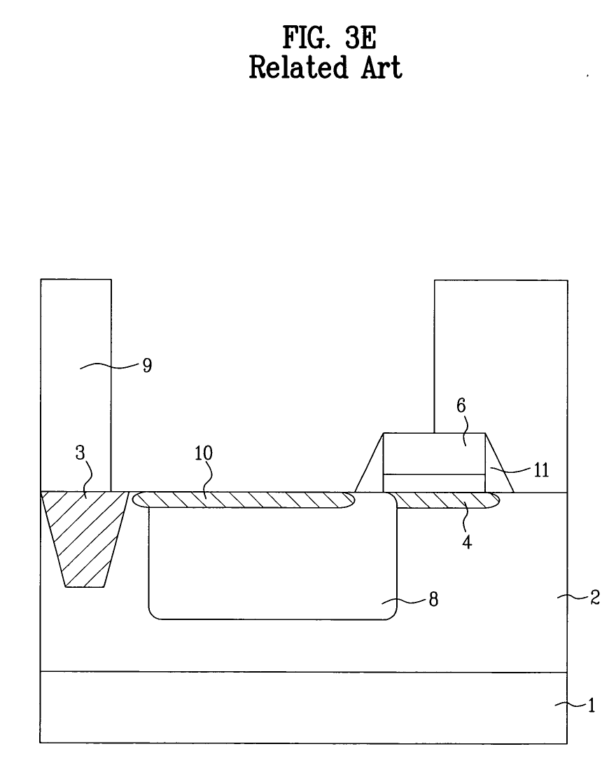

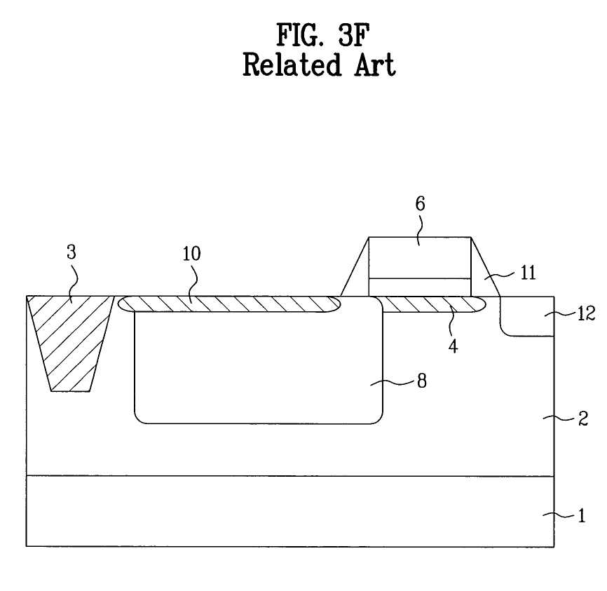

### DETAILED DESCRIPTION OF THE INVENTION

Reference will now be made in detail to exemplary embodiments of the present invention, examples of which are illustrated in the accompanying drawings. Wherever possible, the same reference numbers will be used throughout the drawings to refer to the same or similar parts.

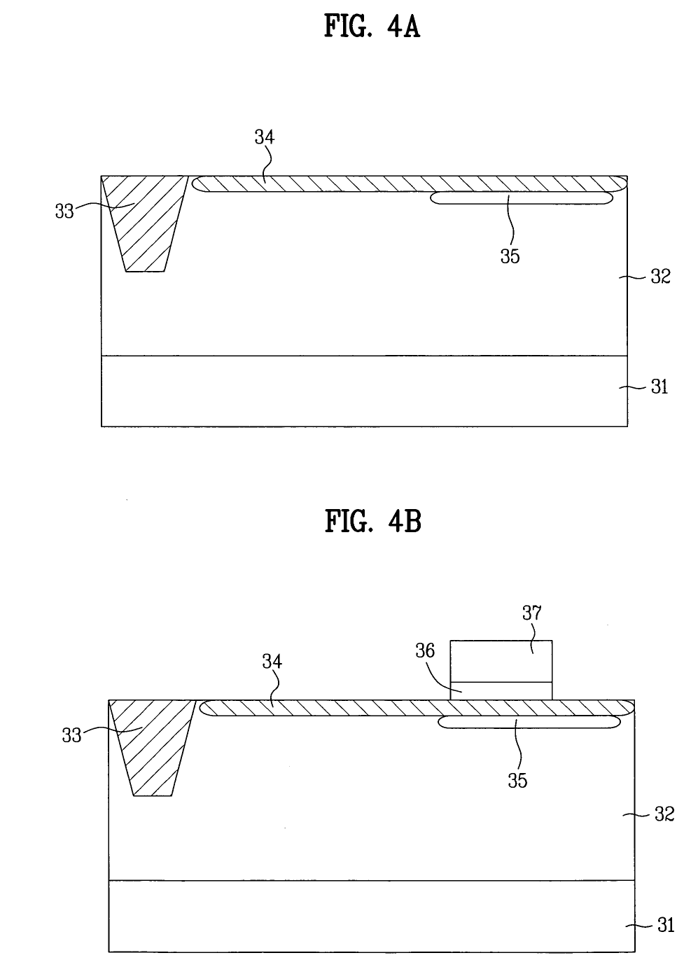

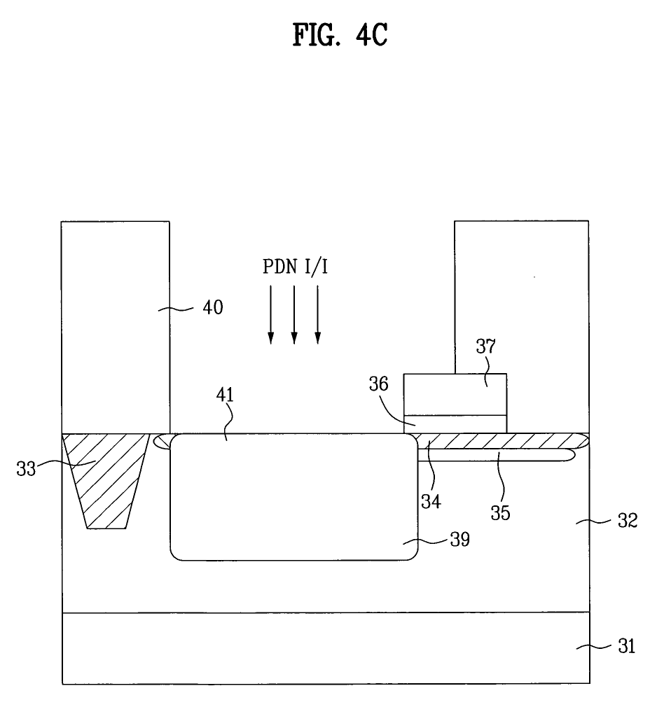

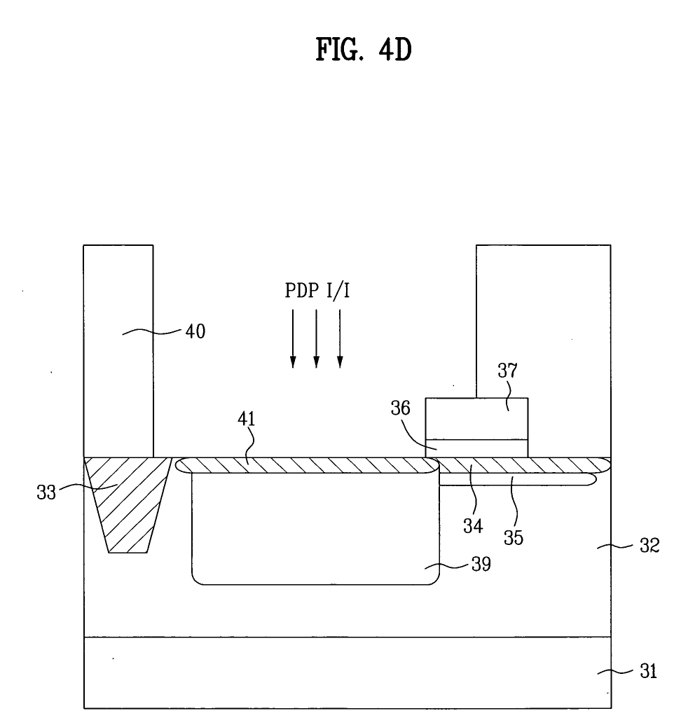

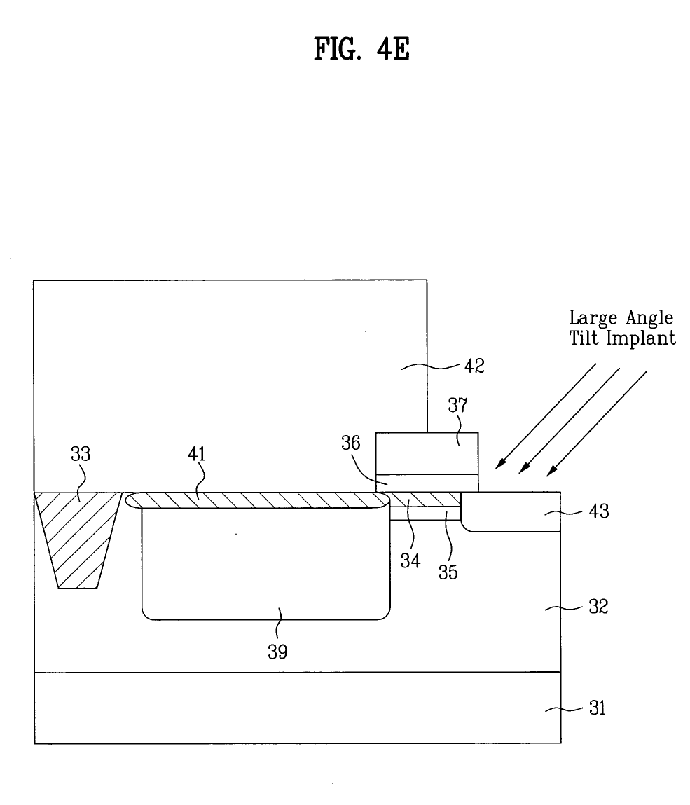

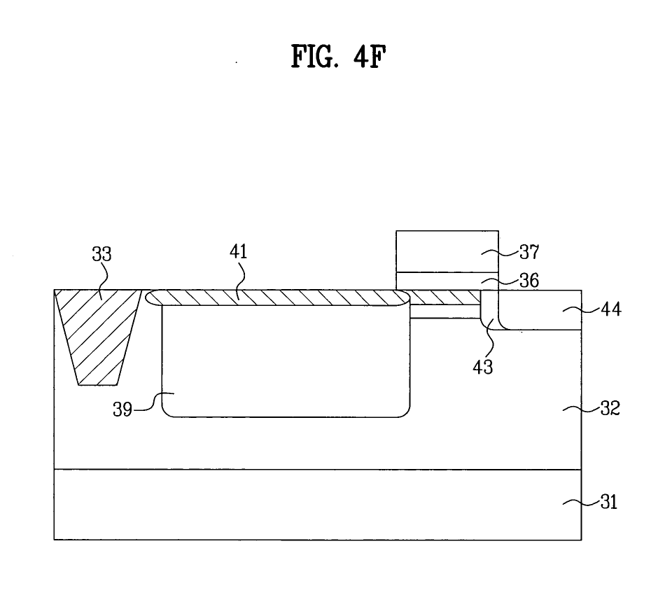

As shown in FIG. 4A, a lightly doped P type (P—) epitaxial layer 32 is formed on a P type semiconductor substrate 31 defined by an active area and a device isolation area using a mask. Then, the lightly doped P type epitaxial layer 32 is etched at a predetermined depth by exposing and developing processes using the mask to form a trench. An oxide film is formed on the substrate so that the trench is filled with the oxide film. The oxide film is patterned by a chemical mechanical polishing (CMP) process to remain in the trench, so that a device isolation film 33 is formed in the device isolation area.

P type impurity ions are implanted into the epitaxial layer of the active area to form a first P type impurity ion area 34 on the surface of the epitaxial layer 32. The first P type impurity ion area 34 is used to control a threshold voltage in a channel region of a transfer transistor and to pin a surface voltage in a photodiode area so as to reduce a dark current.

Subsequently, an N type impurity ion area 35 is formed below the first P type impurity ion area 34 for the transfer transistor by impurity ion implantation using a mask. The N type impurity ion area 35 serves as a transfer path for optical charges.

As shown in FIG. 4B, a gate insulating film and a conductive layer are sequentially formed on the entire surface of the epitaxial layer 32 and then selectively removed to form a gate insulating film 36 and a gate electrode 37 of each transistor including the transfer transistor.

As shown in FIG. 4C, a photoresist film is coated on the entire surface and then removed by exposing and developing processes to form a photoresist pattern 40 that exposes the photodiode area. The photoresist pattern 40 is formed to partially cover the active area adjacent the device isolation film 33 and the gate electrode 37. N type impurity ions are implanted into the epitaxial layer 32 of the exposed photodiode area by high energy ion implantation to form a second N type impurity ion area 39. The photoresist pattern 40 is then removed.

As shown in FIG. 4D, after the second N type impurity ion area 39 is formed, a photoresist pattern 40 is formed to expose the photodiode area. Then, P type impurity ions are implanted into the surface of the second N type impurity ion area 39 to form a second P type impurity ion area 41 of the photodiode area.

As shown in FIG. 4E, a photoresist pattern 42 is formed above the epitaxial layer 32 to cover the device isolation area and the photodiode area. Then, a third P type impurity ion area 43 is formed in a source/drain area, or a floating diffusion layer, of the transfer transistor. The third P type impurity ion area 43 may be formed by P type large angle tilt ion implantation around sides of the gate electrode. The third P type impurity ion area is extended to a portion below the transfer transistor by controlling an ion implantation angle. B, BF₂, Ga, In, etc. ions may be used as the P type impurity ions.

As shown in FIG. 4F, the photoresist pattern 42 is removed and then a source and drain area 44 is formed by heavily implanting N type impurity ions using the gate electrode 37 as a mask. N type impurity ions are heavily implanted into the P type impurity ion area to form a P type LDD structure. The optical charges transferred through the N type impurity ion area 35 formed below the first P type impurity ion 34 are controlled using the P type LDD structure.

Then, color filter layers and microlenses may be formed. Thus, the CMOS image sensor according to the present invention is completely fabricated.

In the CMOS image sensor fabricated according to an exemplary embodiment of the present invention, the N type impurity ion area is formed below the gate electrode of the transfer transistor to increase the transfer path for the optical charges. A dead zone is thereby prevented from occurring without degradation of the dark current characteristic.

Further, the transfer path for the optical charges is formed in a portion where no potential barrier is formed by the P type impurity ion area on the surface of the epitaxial layer. Thus, transfer efficiency of the optical charges is not deteriorated even if the P type impurity ion area is extended or its doping level is increased. Thus, it is possible to reduce the dark current of the CMOS image sensor.

Moreover, since the LDD structure having the P type impurity ion area is formed in the source and drain area of the transfer transistor, it is possible to reduce leakage current of the transfer transistor.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A CMOS image sensor comprising:
a first conductive type semiconductor substrate defined by an active area and a device isolation area;
a device isolation film formed in the first conductive type semiconductor substrate corresponding to the device isolation area;
a gate electrode formed on the first conductive type semiconductor substrate corresponding to a transistor area of the active area;
a second conductive type first impurity ion area and a first conductive type first impurity ion area formed with a deposition structure in the semiconductor substrate below the gate electrode;
a second conductive type second impurity ion area formed in the semiconductor substrate of a photodiode area; and
a first conductive type second impurity ion area formed on a surface of the second conductive type second impurity ion area.

2. The CMOS image sensor of claim 1, further comprising a source and drain area formed in the semiconductor substrate at sides of the gate electrode, and a first conductive type third impurity ion area formed in the semiconductor substrate of the source and drain area.

3. The CMOS image sensor of claim 2, wherein the first conductive type third impurity ion area is formed by implanting first conductive type impurity ions in a tilt ion implantation manner.

4. The CMOS image sensor of claim 2, wherein the first conductive type third impurity ion area is extended to a portion below the gate electrode by control of an ion implantation angle.

5. The CMOS image sensor of claim 2, wherein the first conductive type impurity ions for the first conductive type third impurity ion area are any one of B ions, BF₂ ions, Ga ions, and In ions.

6. A method for fabricating a CMOS image sensor comprising:
forming a first conductive type first impurity ion area on a surface of an active area of a first conductive type semiconductor substrate defined by the active area and a device isolation area;
forming a second conductive type first impurity ion area below the first conductive type first impurity ion area corresponding to a transistor area of the active area;
forming a gate electrode on the semiconductor substrate corresponding to the transistor area;
forming a second conductive type second impurity ion area in the semiconductor substrate corresponding to a photodiode area of the active area; and
forming a first conductive type second impurity ion area on a surface of the second conductive type second impurity ion area.

7. The method of claim 6, further comprising:
forming a first conductive type third impurity ion area in the semiconductor substrate at sides of the gate electrode; and
forming a source and drain area in the semiconductor substrate of the source and drain area.

8. The method of claim 7, wherein the first conductive type third impurity ion area is formed by implanting first conductive type impurity ions in a tilt ion implantation manner.

9. The method of claim 7, wherein the first conductive type third impurity ion area is extended to a portion below the gate electrode by control of an ion implantation angle.

10. The method of claim 7, wherein the first conductive type impurity ions for the first conductive type third impurity ion area are any one of B ions, BF₂ ions, Ga ions, and In ions.
